(19) United States
(12) Patent Application Publication
(10) Pub. No.: US 2025/0167167 A1
(43) Pub. Date: May 22, 2025

(54) Die Stacking with Integrated Thermal Treatment

(71) Applicant: Applied Materials, Inc., Santa Clara, CA (US)

(72) Inventors: Ying WANG, Singapore (SG); Ke ZHENG, Singapore (SG); Raymond HUNG, Palo Alto, CA (US); ChangBum YONG, Singapore (SG); Guan Huei SEE, Singapore (SG); Gaurav MEHTA, Singapore (SG)

(21) Appl. No.: 18/408,820

(22) Filed: Jan. 10, 2024

Related U.S. Application Data
(60) Provisional application No. 63/600,588, filed on Nov. 17, 2023.

(51) Int. Cl. H01L 23/00; H01L 25/00

(52) U.S. Cl. CPC H01L 24/80; H01L 25/50; H01L 2224/802; H01L 2224/80895; H01L 2224/80896

(57) ABSTRACT

Methods and apparatus for substrate processing are provided. In some embodiments, a substrate processing method includes: sequentially stacking a plurality of dies on a substrate into a stacked assembly; thermally treating the plurality of dies; and stacking at least one additional die atop the thermally treated plurality of dies.

### CROSS-REFERENCE TO RELATED APPLICATIONS

This application claims benefit of U.S. provisional patent application Ser. No. 63/600,558, filed Nov. 17, 2023 which is herein incorporated by reference in its entirety.

### FIELD

Embodiments of the present disclosure generally relate to substrate processing, and more particularly to thermal treatment of dies in a bonder system.

### BACKGROUND

In semiconductor manufacturing, a die is the area of a substrate (e.g., silicon wafer) on which a functional circuit is fabricated. Often, many (e.g., hundreds) of dies may be fabricated on each substrate. Also, in some instances, dies may be stacked and permanently bonded to one another and to a substrate silicon wafer.

When a die is placed on a substrate or on another die, the forces holding the die in place are relatively weak tacking forces. As dies are stacked up, unbalanced stress of the front side and back side of dies may accumulate, and create a large internal stress within the die stack. Two weakly bonded dielectric surfaces (e.g., from weak hydrogen/van der Waal interaction) from die tacking may not withstand a stress over a certain threshold and can separate because of the stress.

The inventors have observed that delamination between die and substrate and/or between dies can happen during die stacking. Such delamination can become worse as more dies are stacked. Delamination leads to several issues, such as reduced yields due to die dropping, poor reliability, and poor electrical connectivity in the delaminated area.

Thus, the inventors have provided methods, systems, and apparatus that can reduce or eliminate delamination between die and substrate and/or between dies can happen during die stacking.

### SUMMARY

Methods and apparatus for substrate processing are provided herein. In some embodiments, an method for substrate processing includes: sequentially stacking a plurality of dies on a substrate into a stacked assembly; thermally treating the plurality of dies; and stacking at least one additional die atop the thermally treated plurality of dies.

In some embodiments, an integrated bonder system for processing a substrate includes: a mainframe comprising a substrate handling system; a thermal treatment chamber connected to the mainframe, the thermal treatment chamber configured to perform rapid thermal processing on a substrate and a plurality of dies sequentially stacked on the substrate; a bonding chamber connected to the mainframe; a plasma chamber connected to the mainframe; a wet clean chamber connected to the mainframe; and a UV chamber connected to the mainframe.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 shows a schematic view of an integrated bonder system in accordance with some embodiments of the present disclosure.

FIGS. 2A-2H schematically depict a workflow in an integrated bonder system in accordance with some embodiments of the present disclosure.

FIGS. 3A and 3B show schematic views of thermal treatment chambers in accordance with some embodiments of the present disclosure.

FIG. 4 depicts a method for substrate processing in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a substrate processing method and system are provided herein to improve die tacking by reducing or eliminating delamination between die and substrate and/or between dies during die stacking.

To improve die tacking, in some embodiments, an integrated bonder system may be used to perform thermal treatment of stacked dies during sequential stacking of the dies on a substrate. In some embodiments, the integrated bonder system may include a thermal treatment chamber that may perform thermal treatments on weakly tacked dies that may convert weak hydrogen/van der Waal interaction to stronger covalent bonding at a dielectric bonding interface (e.g., die-to-substrate and/or die-to-die), allowing for further stacking of more die layers. Performing thermal treatment of the stacked dies and substrate in a thermal chamber integrated with the integrated bonder system may allow for better defectivity control and scheduling/throughput management. Also, processing the stacked dies within the integrated bonder system maintains the stacked dies in a clean micro-environment of the integrated bonder system, which may facilitate clean and delamination-free die stacking of more die layers.

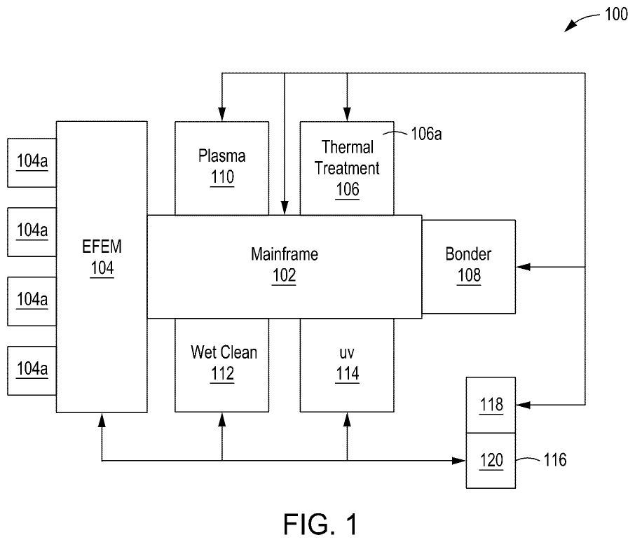

In some embodiments, and as shown in FIG. 1, an integrated bonder system 100 for processing a substrate may include a mainframe 102 having a substrate handling system, an equipment front end module (EFEM) 104 connected to the mainframe, and a plurality of processing chambers coupled to the mainframe. In some embodiments, the plurality of processing chambers include a thermal treatment chamber 106 connected to the mainframe 102, a bonding chamber 108 connected to the mainframe 102, a plasma chamber 110 connected to the mainframe 102, a wet clean chamber 112 connected to the mainframe 102, and a UV chamber 114 connected to the mainframe 102. In some embodiments, the system 100 may include a degas chamber. In some embodiments, the system may include an anneal chamber.

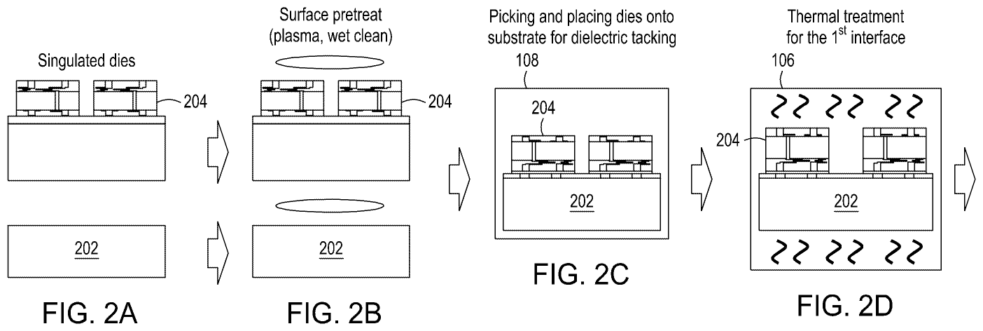

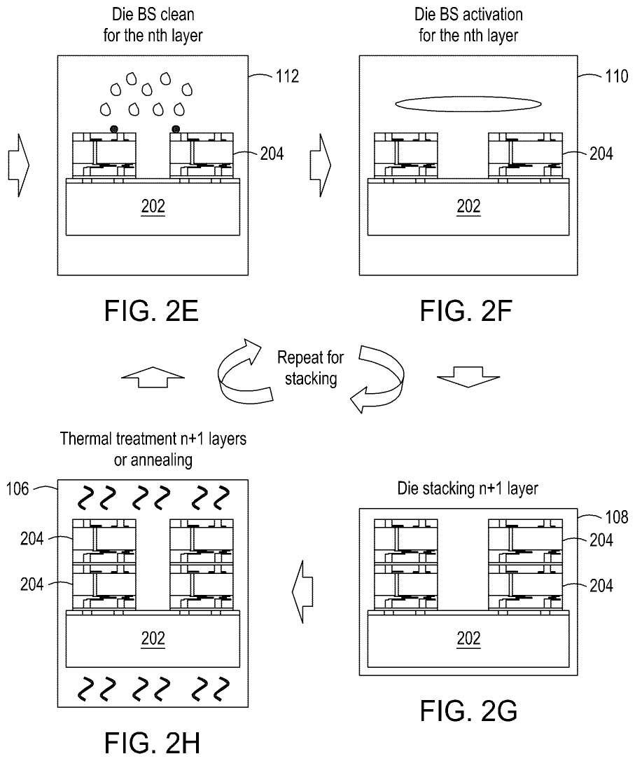

In some embodiments, the EFEM 104 is configured to transport substrates 202 and dies 204 (FIG. 2A) between storage carriers 104a and the mainframe 102. The substrate handling system of the mainframe 102 may include a substrate handling robot (not shown) used to transport substrates and dies within the integrated bonder system 100 in a processing sequence to provide certain levels of processing throughput.

The thermal treatment chamber 106 may be configured to perform a thermal treatment process on a substrate (e.g., 202) and a plurality of dies (e.g., 204) that are sequentially stacked on the substrate into a multi-layer stacked assembly, as discussed in greater detail below. In some embodiments, the thermal treatment chamber is configured to perform a thermal treatment process on a substrate and a plurality of dies that are sequentially stacked on the substrate into a multi-layer stacked assembly to convert weaker van der Waal tacking forces (e.g., substrate-to-die, die-to-die) to stronger covalent bonds. In some embodiments, the thermal treatment chamber 106 may be configured to perform rapid thermal processing on a substrate and a plurality of dies that are sequentially stacked on the substrate at a temperature of 100° C. to about 400° C. and ramp temperature up to 100° C. per second. In some embodiments, the thermal treatment chamber 106 may also be configured to perform annealing on thermally treated dies and at least one additional die stacked atop the thermally treated dies.

In some embodiments, and as shown in FIGS. 2D and 2H, the thermal treatment chamber 106 has an interior 106a that is configured to receive a plurality of dies 204 stacked on a substrate 202 for thermal treatment. In some embodiments, the thermal treatment chamber 106 may be configured to maintain a temperature of about 100° C. to about 400° C. within the interior 106a, and may be configured to maintain the temperature for up to 5 hours. In some embodiments, the thermal treatment chamber 106 may be configured to ramp the temperature of the interior 106a at a rate of about 100° C. per second.

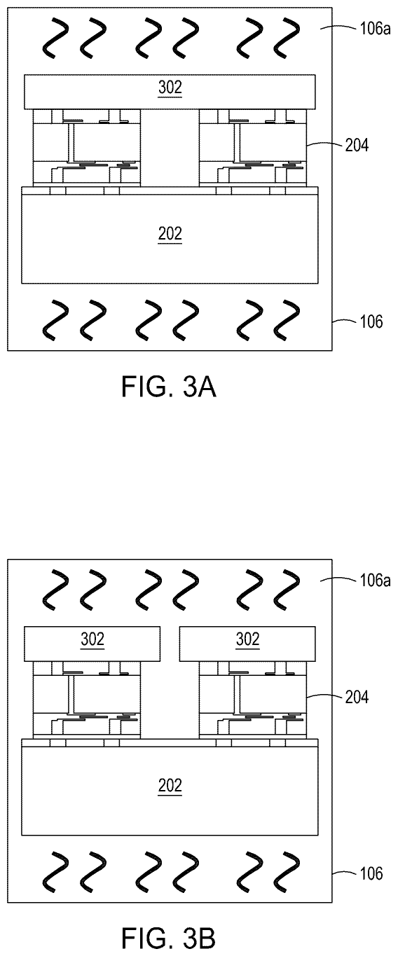

In some embodiments, and as shown in FIGS. 3A and 3B, the thermal treatment chamber 106 may have a thermally conductive structure 302 within the interior 106a. The thermally conductive structure 302 (e.g., a heated surface) may be configured to contact at least one of the plurality of dies. In some embodiments, the thermally conductive structure 302 may be configured to contact at least one of the plurality of dies 204 without applying pressure on the dies 204. In some embodiments, the thermally conductive structure 302 may apply an effective pressure of 10-100 MPa on at least one of the plurality of dies 204. In some embodiments, and as shown in FIG. 3A, one thermally conductive structure 302 may be used to contact a plurality of dies 204. In some embodiments, and as shown in FIG. 3B, each die 204 may be contacted by a corresponding thermally conductive structure 302.

In some embodiments, and as shown in FIG. 2D, the thermal treatment chamber 106 may be coupled to at least one of a vacuum source 206, a supply of inert gas (e.g., Ar, N2, He) 208, or a supply of reducing gas (hydrogen containing) 210. In some embodiments, the pressure in the interior 106a of the thermal treatment chamber may be controlled to be a few mTorr to 760 Torr.

In some embodiments, and as shown in FIG. 2E, the wet clean chamber 112 may be configured to perform a wet clean process on a backside of each stacked die 204 to improve further stacking of dies. In some embodiments, and as shown in FIG. 2F, the plasma chamber 110 may be configured to activate a backside of each stacked die 204 to improve tacking of a next die to be stacked. In some embodiments, the UV chamber 114 may be configured to perform a UV treatment, such as a bonding process, on the substrate and the plurality of stacked dies 204.

In some embodiments, and as shown in FIG. 1, the integrated bonder system 100 may include a controller 116 that includes a processor 118 and a memory 120 configured to control one or more chambers of the integrated bonder system 100. In some embodiments, and as described in greater detail below, the controller 116 may be configured to control the bonding chamber 108 to sequentially stack a plurality of dies 204 on a substrate 202 into a stacked assembly, control the thermal treatment chamber 106 to thermally treat the plurality of dies 204, and control the bonding chamber 108 to stack at least one additional die 204 atop the thermally treated plurality of dies 204.

In some embodiments, and as described in greater detail below, the controller 116 may be configured to control the wet clean chamber 112 to clean a backside of each die 204 after stacking each die 204, and to control the plasma chamber 110 to activate a backside of each die 204 after stacking each die.

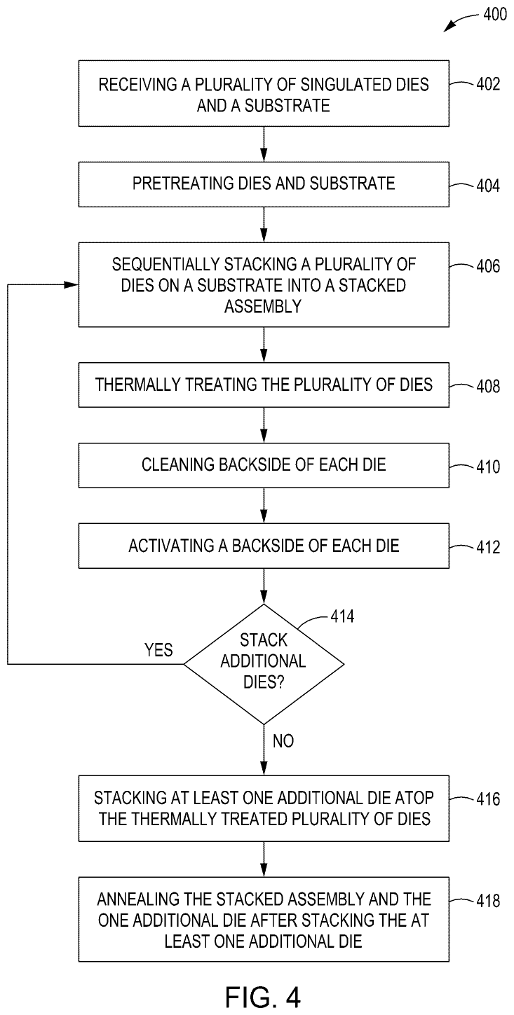

According to some embodiments, and as shown in FIGS. 2A and 4, at block 402 a substrate processing method 400 may include receiving a substrate 202 and a plurality of dies 204 (e.g., singulated dies). In some embodiments, and as shown in FIG. 2A, the dies 204 may be received on a dicing tape or a carrier. In some embodiments, the substrate 202 and the dies 204 may be received by the EFEM 104 of the integrated bonder system 100.

In some embodiments, and as shown in FIGS. 2B and 4, at block 404 the method 400 may include pretreating the substrate 202 and the dies 204. In some embodiments, the dies 204 and the substrate 202 may be pretreated separately. In some embodiments, the pretreatment may include a wet clean process and a plasma treatment process. In some embodiments, the wet clean process may be performed in a wet clean chamber, such as the wet clean chamber 112 of the integrated bonder system 100. In some embodiments, the plasma treatment process may be performed in a plasma chamber, such as the plasma chamber 110 of the integrated bonder system 100.

In some embodiments, and as shown in FIGS. 2C, 2G, and 4, at block 406 the method 400 may include sequentially stacking a plurality of dies 204 on the substrate 202 into a stacked (e.g., a multi-layered) assembly. In FIG. 2C a first layer of dies 204 are stacked directly on the substrate 202. In FIG. 2G, a second layer of dies 204 may be stacked on the dies 204 of the first layer. The dies 204 may be picked and placed onto the substrate 202 and onto other dies 204 for dielectric tacking whereby the tacking forces may be relatively weak hydrogen/van der Waal forces. In some embodiments, the picking and placement of dies 204 may be performed in a bonding chamber, such as the bonding chamber 108 of the integrated bonder system 100.

In some embodiments, and as shown in FIGS. 2D and 2H and 4, at block 408 the method 400 may include thermally treating the plurality of dies 204. In some embodiments, and as shown in FIGS. 2D and 2H, the substrate 202 and the stacked dies 204 may be thermally treated in a thermal treatment chamber, such as the thermal treatment chamber 106 of the integrated bonder system 100. In some embodiments, the thermal treatment may be performed in a thermal treatment chamber that is separate from the integrated bonder system 100. In some embodiments, the thermal treatment may include at least one of a furnace process, oven process, thermal degassing, rapid thermal process, radiation heating process, or microwave annealing process.

In some embodiments, the thermal treatment may be performed after stacking a certain number of dies 204 (e.g., layers) on the substrate 202. In some embodiments, the certain number may be less than or equal to half of the plurality of dies 204 of the stacked assembly.

In some embodiments, and as shown in FIGS. 2D, 2G, and 2H, the thermal treatment and stacking of dies 204 may be performed in separate processing chambers of the integrated bonder system 100. In some embodiments, the thermal treatment may be performed in an inert gas environment (e.g., Ar, N2, He, or mixture) or a reducing environment (e.g., hydrogen-containing).

In some embodiments, and as shown in FIG. 3, thermal treatment may include contacting at least one of the plurality of dies 204 with a thermally conductive structure 302. In some embodiments, the thermally conductive structure 302 may be used to apply pressure to the plurality of dies 204. In some embodiments, the thermal treatment may include applying pressure on at least one die of the plurality of dies. The pressure may be about 10 MPa to about 100 MPa.

In some embodiments, the thermal treatment may be performed in a vacuum. In some embodiments, the thermal treatment may be performed at a pressure of about 3 mTorr to about 760 Torr. In some embodiments, the method 400 may be performed without breaking vacuum between stacking the dies 204 and thermally treating the dies 204.

In some embodiments, the thermal treatment may be performed at a substrate temperature of about 100° C. to about 400° C. In some embodiments, the thermal treatment may be performed for about 0.5 minutes to about 1 hour. In some embodiments, the thermal treatment may include ramping temperature up to 100° C. per second. In some embodiments, the thermal treatment may be performed in less than a minute at a temperature of about 400° C.

In some embodiments, and as shown in FIGS. 2E and 4, at block 410 after stacking the dies 204 of the first layer, the backside of each stacked die 204 may be cleaned in a wet clean chamber, such as the wet clean chamber 112 of the integrated bonder system 100.

In some embodiments, and as shown in FIGS. 2F and 4, at block 412 after stacking the dies 204 of the first layer, the backside of each stacked die 204 may be activated by a plasma process in a plasma chamber, such as the plasma chamber 110 of the integrated bonder system 100. In some embodiments, the backside of each stacked die 204 may be activated using wet chemistry activation without a plasma process.

In some embodiments, and as shown in FIGS. 2G, 2H, and 4, if additional dies are to be added to the stacked assembly of dies 204 (YES at block 414), blocks 406-412 may be repeated to sequentially stack dies 204. In some embodiments, and as shown in FIG. 2G, the stacking of the dies 204 of the second layer may be performed in a bonding chamber, such as the bonding chamber 108 of the integrated bonder system 100.

In some embodiments, the thermal treatment at block 408 may be skipped between one or more sequences of stacking the plurality of dies 204. In some embodiments, the thermal treatment may be performed after stacking a certain number of dies of the plurality of dies 204 on the substrate 202. The certain number may be less than or equal to half of the plurality of dies 204.

In some embodiments, and as shown in FIG. 4, at block 416 if no additional dies are to be added to the stacked assembly of dies 204 (NO at block 414), the method 400 may include stacking at least one additional die 204 atop the thermally treated plurality of dies 204 as shown in FIG. 2G. In some embodiments, and as shown in FIG. 4, at block 418, the method 400 may include annealing the stacked assembly and the one additional die 204 after stacking the at least one additional die. The thermal treatment may be performed at at least one of a lower temperature or a shorter duration than the annealing. In some embodiments, the thermal treatment may be performed for up to 1 hour and the annealing may be performed for up to 5 hours. In some embodiments, and as shown in FIG. 2H, the annealing may be performed in the thermal treatment chamber 106 of the integrated bonder system 100. In some embodiments, the annealing may be performed in an annealing chamber of the integrated bonder system 100 that is different than the thermal treatment chamber 106. In some embodiments, the annealing may be performed in an annealing chamber that is separate from the integrated bonder system 100.

In some embodiments, the method 400 may include performing a UV treatment on the stacked assembly of dies 204 and the at least one additional die 204 atop the stacked assembly of dies 204. In some embodiments, the UV treatment may include a UV bonding treatment. In some embodiments, the UV treatment may include a radiation process to reduce adhesion between the plurality of dies 204 and the dicing tape or carrier. For example, the UV chamber may be configured to direct ultraviolet radiation at the dicing tape or carrier to reduced adhesion between the plurality of dies 204 and the dicing tape or carrier to facilitate easier removal of the plurality of dies 204 for picking and placing on the substrate 202.

In some embodiments, the UV treatment may be performed in a UV chamber, such as the UV chamber 114 of the integrated bonder system 100.

As described above, embodiments of systems and methods may be provided to improve die tacking by performing thermal treatment during sequential stacking of dies on a substrate. As a result of the thermal treatment, relatively weak van der Waal tacking forces may advantageously be converted to stronger covalent bonds. The systems and method described herein facilitate clean and reduced delamination or delamination-free die stacking of a plurality of layers of dies on a substrate, as well as enable stacking of greater numbers of layers of dies on a substrate, which can increase processing yields.

While the foregoing is directed to embodiments of the present disclosure, other and further embodiments of the disclosure may be devised without departing from the basic scope thereof.

1. A substrate processing method, comprising:
sequentially stacking a plurality of dies on a substrate into a stacked assembly;
thermally treating the plurality of dies; and
stacking at least one additional die atop the thermally treated plurality of dies.

2. The method of claim 1, further comprising annealing the stacked assembly and the at least one additional die after stacking the at least one additional die, wherein thermally treating is performed at at least one of a lower temperature or a shorter duration than the annealing.

3. The method of claim 1, wherein thermally treating is performed after stacking a certain number of dies of the plurality of dies on the substrate.

4. The method of claim 3, wherein the certain number is less than or equal to half of the plurality of dies.

5. The method of claim 1, wherein thermally treating and stacking are performed in separate processing chambers of an integrated bonder system.

6. The method of claim 1, wherein thermally treating includes contacting at least one of the plurality of dies using a thermally conductive structure.

7. The method of claim 1, wherein thermally treating includes applying a pressure on at least one die of the plurality of dies.

8. The method of claim 7, wherein the pressure is about 10 to about 100 MPa.

9. The method of claim 1, further comprising cleaning and activating a backside of each die.

10. The method of claim 9, wherein activating includes plasma treatment.

11. The method of claim 9, wherein activating includes wet chemistry activation.

12. The method of claim 1, wherein thermally treating is performed in a vacuum.

13. The method of claim 1, wherein thermally treating is performed at a pressure of 3 mTorr to 760 Torr.

14. The method of claim 1, wherein thermally treating is performed in an inert gas environment or a reducing environment.

15. The method of claim 1, wherein thermally treating is performed at a substrate temperature of 100° C. to 400° C.

16. The method of claim 1, wherein thermally treating is performed for 0.5 minutes to 1 hour.

17. The method of claim 1, wherein thermally treating includes ramping temperature up to 100° C. per second.

18. An integrated bonder system for processing a substrate, comprising:
a mainframe comprising a substrate handling system,
a thermal treatment chamber connected to the mainframe, the thermal treatment chamber configured to perform rapid thermal processing on a substrate and a plurality of dies sequentially stacked on the substrate;
a bonding chamber connected to the mainframe;
a plasma chamber connected to the mainframe;
a wet clean chamber connected to the mainframe; and
a UV chamber connected to the mainframe.

19. The system of claim 18, further comprising a controller including a processor and a memory configured to:
control the bonding chamber to sequentially stack a plurality of dies on a substrate into a stacked assembly;
control the thermal treatment chamber to thermally treat the plurality of dies; and
control the bonding chamber to stack at least one additional die atop the thermally treated plurality of dies.

20. The system of claim 19, wherein the controller is configured to control the wet clean chamber to clean a backside of each die after stacking, and control the plasma chamber to activate a backside of each die after stacking.
